(19) United States
(12) Patent Application Publication
(10) Pub. No.: US 2026/0305270 A1
(43) Pub. Date: Oct. 1, 2026

(54) PATTERNING METHOD APPLICABLE IN SEMICONDUCTOR PROCESSING

(71) Applicant: IMEC VZW, Leuven (BE)

(72) Inventors: Frederic Lazzarino, Hamme-Mille (BE); Ru-Gun Liu, Hsinchu County (TW)

(21) Appl. No.: 19/635,608

(22) Filed: Mar. 31, 2026

(30) Foreign Application Priority Data
Apr. 1, 2025 (EP) 25167726.6

(51) Int. Cl. H10P 76/40; H10P 50/00

(52) U.S. Cl. CPC H10P 76/4085; H10P 50/73

(57) ABSTRACT

A target layer to be patterned is formed on a support substrate is provided. An etch stop layer and a first mask layer are formed on the target layer. The first mask layer is patterned to provide a two-dimensional array of openings. A first directional etching step enlarges the openings to form a pattern of parallel first trenches in the first mask layer. A second mask layer is formed. The second mask layer is patterned according to the same array of openings, and the second mask layer is subjected to a second directional etching step. This enlarges the openings in the second mask layer to form second parallel trenches extending in a direction that crosses the direction of first trenches. The second directional etching step removes exposed portions of the first mask layer to form a pattern of pillars, and the pattern of pillars is transferred to the target layer.

### CROSS-REFERENCE TO RELATED APPLICATION(S)

The present application is a non-provisional patent application claiming priority to European Patent Application No. 25167726.6, filed Apr. 1, 2025, the contents of which are hereby incorporated by reference.

### FIELD OF THE DISCLOSURE

The present disclosure relates to semiconductor fabrication processes, including patterning methods applicable in the processes.

### BACKGROUND

Semiconductor fabrication processes rely on advanced lithography and etch technologies using nanometer-scale patterns in the front-end-of-line and at (e.g., the deepest) levels of the back-end-of-line process sequences. Some (e.g., advanced) EUV lithography tools are limited in terms of the obtainable resolution and employ (e.g., expensive) multiple exposure methods for printing features smaller than the resolution limit.

Producing an array of pillar-shaped features at sub-resolution pitch can be challenging using conventional single or multiple exposure lithography tools.

### SUMMARY

The present disclosure provides methods in accordance with the appended claims. The present disclosure provides a target layer that may be formed and patterned on a support substrate. An etch stop layer and a first mask layer are produced (e.g., in that order) on the target layer. According to example embodiments of the present disclosure, the first mask layer is patterned into a (e.g., regular) two-dimensional array of openings. A regular array may be an array, wherein the openings have the same in-plane dimensions and are ordered according to a repetitive pattern. For example, this may be a square or rectangular pattern wherein the openings are arranged in perpendicular rows and columns. The openings also may be arranged in rows and columns, which are at an angle different from 90°. This may be done by patterning a resist layer and transferring the resist pattern to the first mask layer, wherein the transfer may involve thinning of the first mask layer and/or removing one or more upper sublayers of the first mask layer when the latter is a multilayer stack. In a first directional etching step, the openings in the first mask layer are enlarged to thereby form a pattern of parallel first trenches in the first mask layer. The trench pattern may be transferred to the etch stop layer at this point, or this transfer can be done later in the process. A second mask layer is produced, which may be after thinning the patterned first mask layer. The second mask layer is patterned into the same regular array of openings, and thereafter the second mask layer is subjected to a second directional etching step, which enlarges the openings in the second mask layer to thereby form second parallel trenches extending in a direction that crosses the direction of the first trenches. The second directional etching also removes portions of the (e.g., possibly thinned) first mask layer exposed to etch species applied in the second directional etching step, so that the latter is eventually patterned into a pattern of pillars. After removing (e.g., stripping) the second mask layer relative to the pillars, the pattern of pillars is transferred to the target layer.

In some example embodiments, when the above sequence is performed using the same rectangular array of openings for patterning both the first and the second mask layers, the directional etching steps are performed in mutually crossing directions that lie between the orthogonal directions of the rows and columns of the rectangular pattern. By applying such directional etch directions, for example at 45° and 135° relative to the column and row directions, the pitch of the resulting array of pillars is smaller than the pitch of the openings in the array. The fabrication of pillar arrays at sub-resolution pitch are thereby provided (e.g., enabled), using (e.g., only) a single lithographic mask.

Another application is provided (e.g., obtained) by applying a rectangular array of openings; however, selected openings may be omitted (e.g., openings are etched in the respective mask layers prior to the respective directional etching steps, except at selected locations). By applying directional etch directions along the row and column directions of the array, a pattern of lines and columns is provided (e.g., obtained), which is otherwise challenging to provide (e.g., obtain) without applying multiple masks.

The present disclosure provides a patterning method that may be used in a semiconductor production process. The method may include one or more steps. For example, the method may include, on a support substrate, producing a target layer that is to be patterned. Further, for example, the steps may include producing an etch stop layer on the target layer and thereafter a first mask layer on the etch stop layer, and/or patterning the first mask layer into a pattern representing a regular two-dimensional array of openings, or an array obtained by omitting one or more openings from a regular two-dimensional array. Additionally, for example, the method may include applying a first directional etching step that is selective relative to the etch stop layer, wherein the first directional etching step enlarges the openings in a first direction, so that the first mask layer is patterned into an array of parallel line-shaped trenches oriented in the first direction, and/or (e.g., thereafter) producing a second mask layer. Moreover, for example, the method may include patterning the second mask layer according to the same pattern representing the array of openings, applying a second directional etching step that is selective relative to the etch stop layer, wherein the second directional etching step enlarges the openings in the second mask layer in a second direction that crosses the first direction, so that the second mask layer is patterned into an array of parallel line-shaped trenches oriented in the second direction, and wherein the second directional etching step also removes portions of the patterned first mask layer exposed to etch species applied in the second directional etching step, so that the first mask layer is patterned into a final pattern comprising an array of pillars and/or lines. Also, for example, the method may include removing the second mask layer relative to the pillars and/or lines, and/or transferring the pattern provided (e.g., defined) by the pillars and/or lines to the target layer.

In the method as provided herein, the term “directional etching” refers to a (e.g., any) method wherein an etch beam is scanned across a substrate so that the beam etches a layer on the substrate at a considerably higher etch rate in the scanning direction than in directions orthogonal to the scanning direction. This makes it possible to pattern the layer by “stretching” an existing opening in the layer by scanning a plasma beam across the opening. The term “scanning” may imply that the beam moves relative to the patterned layer or vice versa, but also refers within the present disclosure (e.g., context) to types of directional etching wherein the beam is stationary but directed according to a given direction to thereby obtain the same elongation effect as a beam that is effectively moving.

According to an example embodiment, the patterned first mask layer is thinned after the first directional etching step and prior to (e.g., the step of) producing the second mask layer.

According to an example embodiment, the pattern of the patterned first mask layer is transferred to the etch stop layer prior to (e.g., the step of) producing the second mask layer, and the pattern of the patterned second mask layer is transferred to the etch stop layer prior to (e.g., the step) of transferring the pattern provided (e.g., defined) by the pillars and/or lines to the target layer.

According to an example embodiment, the pattern of the patterned first mask layer is not transferred to the etch stop layer prior to the step of producing the second mask layer, and the pattern provided (e.g., defined) by the pillars and/or lines is transferred to the etch stop layer before transferring the pattern provided (e.g., defined) by the pillars and/or lines to the target layer.

According to an example embodiment, the regular array of openings may be a rectangular array extending in two perpendicular directions, with one or more openings omitted from the rectangular array. The first direction of the first directional etching step is oriented according to one (e.g., first) of the perpendicular directions of the array of openings, and the second direction of the second directional etching step is oriented according to the other (e.g., second) of the perpendicular directions of the array of openings.

According to an example embodiment, the regular array of openings is a rectangular array extending in two perpendicular directions. The first direction of the first directional etching step is oriented between the two orthogonal directions. The second direction of the second directional etching step is oriented perpendicularly to the first direction.

According to an example embodiment, the first direction is oriented at 45° relative to the two orthogonal directions.

According to an example embodiment, the openings (e.g., each) have (e.g., are holes having) a circular cross-section shape.

According to an example embodiment, the first mask layer comprises a stack of sublayers (e.g., from bottom to top) including a first hardmask layer of a thickness t1, a second hardmask layer of a thickness higher than t1, and a third hardmask layer of a thickness essentially equal to t1. The third hardmask layer is consumed during the transfer of the pattern of openings from a patterned resist layer formed on the first mask layer to the first mask layer, so that the first directional etching step is performed on a stack formed of the first and second hardmask layers.

According to an example embodiment, the second hardmask layer is stripped relative to the first hardmask layer prior to (e.g., the step of producing) the second mask layer.

According to an example embodiment, the second mask layer comprises a stack of sublayers (e.g., from bottom to top) including a first hardmask layer of a thickness t1 and a second hardmask layer of a thickness lower than t1. The second hardmask layer is consumed during the transfer of the pattern of openings from a patterned resist layer formed on the second mask layer to the second mask layer.

### BRIEF DESCRIPTION OF THE FIGURES

The above, as well as additional, features will be better understood through the following illustrative and non-limiting detailed description of example embodiments, with reference to the appended drawings.

FIG. 1 is a diagram illustrating an example of a tool for directional etching according to an example embodiment of the present disclosure.

FIGS. 2A and 2B are diagrams illustrating an example of a process of directional etching according to an example embodiment of the present disclosure.

FIGS. 3, 4, 5, 6, 7, 8, 9, and 10 are diagrams illustrating examples of method steps according to a first example embodiment of the present disclosure, starting from a rectangular array of openings.

FIGS. 11A, 11B, and 11C are diagrams illustrating examples of a pattern including both pillars and line-shaped features, which may be obtained by starting from an array of openings, wherein a number of openings have been omitted from the full array according to an example embodiment of the present disclosure.

FIGS. 12, 13, 14, 15, 16, 17, and 18 are diagrams illustrating a second example embodiment of the present disclosure, wherein a pillar array is obtained at a smaller pitch than the array of openings from which the method starts.

All the figures are schematic, not necessarily to scale, and generally only show parts which are necessary to elucidate example embodiments, wherein other parts may be omitted or merely suggested.

### DETAILED DESCRIPTION

Example embodiments are described more fully hereinafter with reference to the accompanying drawings. That which is encompassed by the claims may, however, be embodied in many different forms and should not be construed as limited to the example embodiments set forth herein; rather, these example embodiments are provided by way of example. Furthermore, like numbers refer to the same or similar elements or components throughout.

Some principles and configurations for realizing directional patterning are, for example, described in U.S. Pat. No. 10,790,155. For example, a plasma beam is scanned relative to a substrate comprising a layer to be patterned. By tuning several parameters and conditions, a plasma beam containing etch species may be directed so that the beam etches a layer on the wafer at a considerably higher etch rate in the scanning direction than in directions orthogonal to the scanning direction. Thus, an existing opening in the layer may “stretch” by scanning a plasma beam across the opening. The term “scanning” may imply that the beam moves relative to the patterned layer or vice versa, and also may refer (e.g., within the present context) to types of directional etching wherein the beam is stationary but directed according to a given direction to thereby obtain the same elongation effect as a beam that is (e.g., effectively) moving. Other, different types of directional etching are possible.

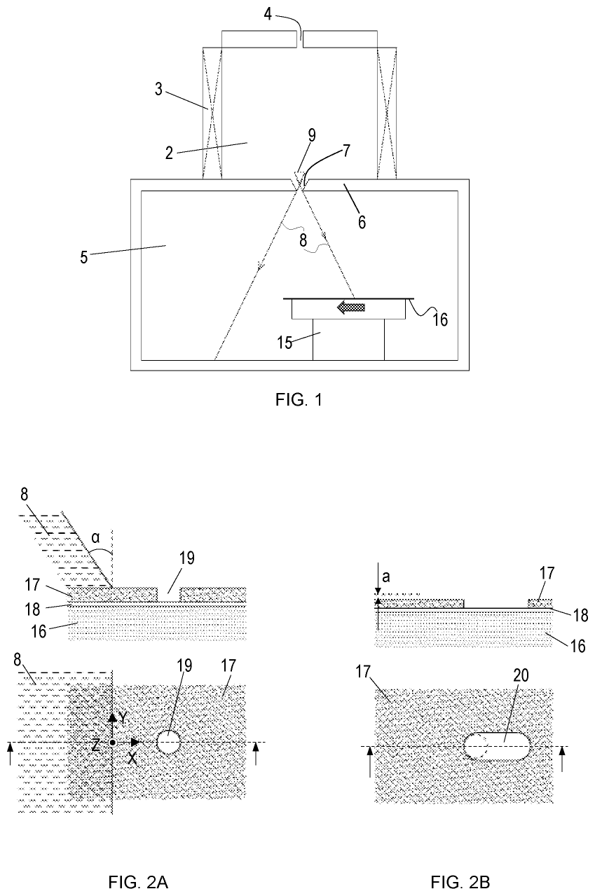

FIG. 1 illustrates a process tool 1 for applying an (e.g., one) example directional etching. The present disclosure is, however, not limited to this technology. The tool 1 includes a plasma chamber 2 surrounded by a radio frequency (RF) coil 3 for generating a plasma in the chamber. A gas inlet 4 provides (e.g., enables) supplying a gaseous substance, while the overall pressure in the plasma chamber is kept at a very low to vacuum level by a suitable vacuum pump installation (not shown). The plasma chamber 2 is separated from a process chamber 5 by a separating wall 6 comprising a slit 7, so that ribbon plasma beams 8 are emitted from the slit. The process chamber is also at a low to vacuum pressure. A meniscus 9 may be mounted in the vicinity of the slit 7 at a distance that can be set to control the propagation direction of the emitted beams 8. A wafer stage 15 is mounted in the process chamber 5. The wafer stage 15 is movable (e.g., linearly) as indicated by the arrow, so that a wafer 16 held by the wafer stage can be moved relative to one of the beams 8, thereby creating the equivalent of the beam 8 being scanned across the wafer 16.

Other directional etching technologies are possible and may be applied in the method according to the present disclosure. Ion beam-based technologies include a method wherein a collimated beam of charged particles, e.g., Ar+, is accelerated on a full wafer at a given angle of incidence. The wafer stage is not moving relative to the beam as the beam is impinging on the full wafer. According to another ion beam-based technology, a collimated beam of ionized gas clusters is accelerated to a spot and scanned across a wafer surface at a given angle of incidence. The angle of incidence of the beam is adjusted by tilting the wafer.

FIGS. 2A and 2B illustrate the directional etching effect on a layer 17 formed on the wafer 16, by using the tool illustrated in FIG. 1. The layer 17 is produced on an etch stop layer 18. Before applying the directional etch process, an opening 19 is formed in the layer 17 by (e.g., standard) lithography and etching, for example, by direct ion etching (DIE). A plasma beam 8 is generated and directed at an angle of incidence α, provided (e.g., defined) as the angle between the beam 8 and the direction perpendicular to the surface of the layer 17. By moving the wafer stage 15 in the direction indicated in FIG. 1, the plasma beam 8 is scanned relative to the layer 17 in a scanning direction X. The angle β between the beam 8 and the scanning direction X is an oblique angle equal to 90°+α. By applying a suitable combination of etch parameters such as the RF power, a DC bias voltage connected to the separator plate 6 and/or the wafer stage 15, the applied etch species, the angle of incidence α and the scanning speed, scanning the beam across the opening 19 may stretch (e.g., has the effect of stretching) the opening in the scanning direction, as illustrated in FIG. 2B. The directional etch process is selective with respect to the etch stop layer 18 so that this layer remains (e.g., essentially) intact and prohibits etching of the underlying support substrate 16. The etch rate in the X-direction is (e.g., considerably) higher than the etch rate in the Y and Z-directions. The result is therefore an elongation of the opening 19 in the X-direction to form a line-shaped trench 20. In the Y-direction, the line is slightly larger than the original diameter of the openings, due to the non-zero etch rate in the Y direction. Etching in the Z-direction causes thinning of the layer 17 by a layer thickness reduction a.

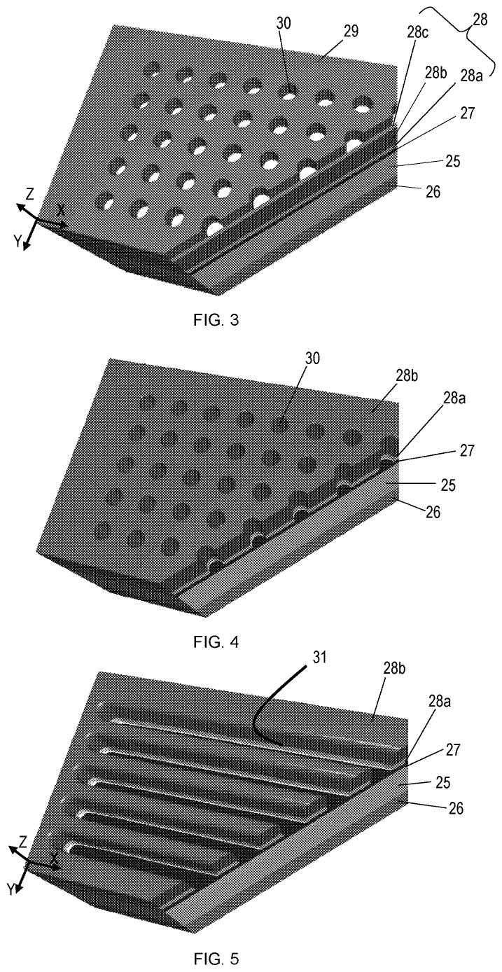

The method, according to a first example embodiment of the disclosure, is illustrated in FIGS. 3 to 13. The aim is to pattern a target layer 25 formed on a support substrate 26. The target layer 25 may be any layer that is (e.g., needs) to be patterned in the course of a semiconductor fabrication process. For example, the target layer 25 may be a dielectric layer formed in the course of the back end of line fabrication of integrated circuits produced on a silicon process wafer, wherein the dielectric layer is (e.g., needs) to be patterned by creating pillar-shaped and/or line-shaped features. The present disclosure is, however, not limited to any type of layer that is to be patterned, nor to any particular stage within a semiconductor fabrication process.

With reference to FIG. 3, on top of the target layer 25, an etch stop layer 27 is formed, followed by a mask layer 28 comprising three sublayers. The three sublayers may include a bottom hardmask layer 28a, a middle hardmask layer 28b, and a top hardmask layer 28c. A mask layer is provided (e.g., defined) within the present disclosure as any layer configured to be patterned into a given pattern, whereafter the pattern is transferred to a layer lying underneath the mask layer. Transferring a pattern from a patterned mask layer to an underlying layer is provided (e.g., defined) within the present disclosure (e.g., context) as etching the underlying layer by an etch process that reproduces the mask pattern in the underlying layer.

The stack of hardmask layers 28a-28c is a (e.g., one) possible example embodiment of a “mask layer,” such as a mask layer referred to in the claims. A mask layer may have other physical appearances within the wider scope of the disclosure. For example, the mask layer may be a single layer, such as, a layer of photoresist. The three-sublayer stack 28a-28c may be used to produce (e.g., very small) features, having dimensions in the order of nanometers. The present disclosure is, however, not limited to any (e.g., particular) dimensions of the patterned features produced by the method of the present disclosure.

The material of the etch stop layer 27 may depend on the hard mask stack material combination, but can be a metal-based material (for example, Ti, TiN, TiO₂, TiON, Ta, TaN . . . ), an aluminium-based dielectric material, or a Si-based material like amorphous Si. The material of the bottom hardmask layer 28a depends on the hard mask stack material combination, but can be a dielectric material used in semiconductor fabrication, like Spin on glass, SiOC, SiO₂, SiN, SiON, SiCN, SiOCN, SiC, or a metal-based material (for example, Ti, TiN, TiO₂, TiON, Ta, TaN . . . ) or an aluminium-based dielectric material. The middle hardmask layer 28b can, for example, be an organic carbon-containing layer like amorphous carbon, Diamond-like Carbon (DLC) or Spin-on Carbon (SOC). The top hardmask layer 28c can be formed of the same material as the bottom layer 28a or top hardmask layer 28c can be formed of one of the materials, such as one of the possible materials provided herein for the bottom layer. The thickness of the top and bottom layers 28a, 28c may be the same, and may have a thickness that is less than (e.g., smaller) than the thickness of the middle layer 28b. In the example embodiment illustrated in the drawings, the thickness of the top and bottom hardmask layers 28a,28c may be in the order of 10-15 nm, while the thickness of the middle layer 28b may be in the order of 50-100 nm.

On top of the mask layer 28, a resist layer 29 is formed and patterned by standard lithography into a pattern of openings 30. For example, the pattern is a (e.g., regular) array of circular openings 30 of equal diameter, but other shapes of the cross-section of the openings are possible as well. As shown, the pattern is a square pattern, e.g., the openings are arranged in orthogonally arranged rows and columns, with constant spacings between openings in the two directions. The diameter of the openings 30 may be in the order of 20 nm. Other array configurations are possible, for example, a hexagonal array of openings.

With reference to FIG. 4, the pattern of openings 30 is transferred to the mask layer 28. This may be done by first etching the top mask layer 28c relative to the resist 29 using a first etch recipe. Then the middle hardmask layer 28b is etched using a second etch recipe that also etches the resist 29. The resist is therefore consumed as the openings are etched in the middle hardmask layer 28b. Then the bottom hardmask layer 28a is etched by a third etch recipe, while (e.g., simultaneously) the top hardmask layer 28c is consumed. The result is shown in FIG. 4. As shown, the pattern of openings 30 has been transferred to the bottom hardmask layer 28a, and the middle hardmask layer 28b, e.g., openings 30 having upright sidewalls are formed through the layer 28a and the layer 28b (e.g., 28a+28b). The term “upright sidewalls” may refer to sidewalls, which are perpendicular to the plane of the support substrate 26 or close to perpendicular, e.g., a small deviation from the geometrical perpendicular orientation is included in the term “upright”.

Here (e.g., at this point), the hardmask layers 28a and 28b are subjected to a directional etch step as described hereinabove, and as illustrated in FIG. 5. A directional etch beam is scanned in a direction parallel to the X-axis of the illustrated orthogonal axis system XYZ, across the pattern of openings, thereby etching layers 28a and 28b selectively with respect to the etch stop layer 27.

The directional etch process elongates the openings 30 by removing material of layers 28a and 28b, to the extent that the openings merge into continuous trenches 31 oriented in the X-direction, as illustrated in FIG. 5. The directional etch process may include multiple scans of the beam in the +X and/or the −X direction. The hardmask layer 28b is thinned as a consequence of a given vertical etch rate, as described above. The width of the trenches may be (e.g., a little) higher (e.g., greater) than the original diameter of the openings, due to a low (e.g., small) etch rate in the Y-direction.

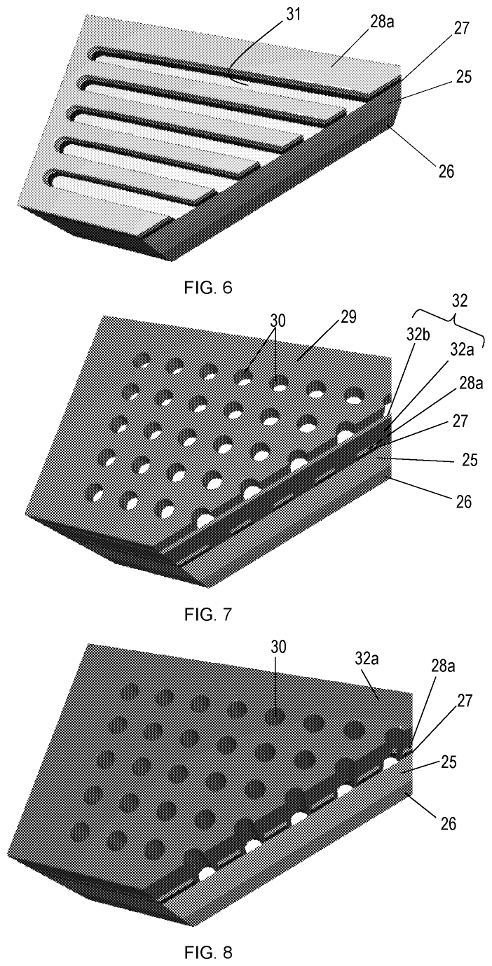

With reference to FIG. 6, the pattern of trenches 31 is transferred to the underlying etch stop layer 27, followed by removing (e.g., stripping) of the middle hardmask layer 28b selectively with respect to the bottom hardmask layer 28a. The target layer 25 may then be (e.g., is now) exposed at the bottom of the transferred trenches 31.

Then, with reference to FIG. 7, a second mask layer 32 is produced, comprising a first hardmask layer 32a and a second hardmask layer 32b.

For example, layer 32a may be formed of the same material and have the same thickness as the middle hardmask layer 28b of the first mask layer 28, while layer 32b may be formed of the same material and have the same thickness as the top hardmask layer 28c of the first mask layer 28. A resist layer 29 is (e.g., again) formed on the second mask layer 32 and patterned into the (e.g., same) square pattern of openings 30, and the openings may be placed at the (e.g., same) locations and may have the (e.g., same) diameter as the openings of the first array.

With reference to FIG. 8, the second square pattern is transferred to the second mask layer 32 in the (e.g., same) way as was described in relation to the first mask layer 28, so that the bottom of the first trenches 31 is exposed at the bottom of the transferred openings 30 through the hardmask layer 32a.

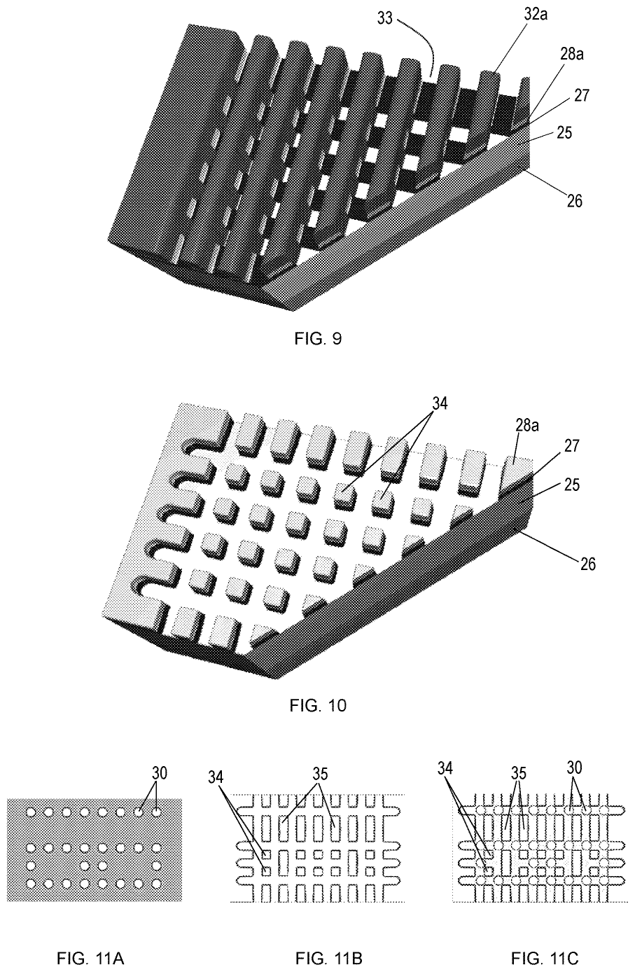

With reference to FIG. 9, a second directional etch process is (e.g., now) applied, by scanning an etch beam in the +Y or −Y direction, or by repeated scanning in the +Y and/or −Y direction. The second directional etch step enlarges the openings 30 by removing material from the hardmask layer 32a. However, at the bottom end of the sidewalls of the openings 30, parallel strips of the bottom hardmask layer 28a have remained after the first directional etch step, and (e.g., hence) regularly spaced portions of these strips are also exposed to the etch beam (e.g., to etch species contained in the etch beam) in the second directional etching step and the portions are removed by the beam relative to the material of the etch stop layer 27. The second directional etch process is applied until the openings 30 merge into second trenches 33 oriented perpendicularly with respect to the first trenches 31. At the bottom of the second trenches 33, regularly spaced portions of the etch stop layer 27 remain.

The pattern of the second trenches 33 is then transferred to the etch stop layer 27, and the hardmask layer 32a is stripped selectively with respect to the hardmask layer 28a, leaving a grid of pillars 34 on the target layer 25 as illustrated in FIG. 10. This grid of pillars can thereafter be transferred to the target layer 25 by a suitable etch process that etches the target layer selectively with respect to the pillars 34. The materials of the mask layers 28 and 32 are chosen so that the above sequence of steps may be provided (e.g., is enabled). Thus, for example, the layer 32a can be removed selectively with respect to the hardmask layer 28a and with respect to the target layer 25.

According to an alternative example embodiment, the pattern of the first trenches 31 is not transferred to the etch stop layer 27 prior to applying the second directional etch process, e.g., the bottom of the transferred trenches 31 is formed by the etch stop layer 27. The etch stop layer 27 is then still present at the bottom of the openings 30 formed through the hardmask layer 32a, and the obtained grid of pillars 34 is transferred to the etch stop layer 27 and to the target layer 25 in consecutive etch steps.

When the array of openings 30 is a square or rectangular array as described above, the resulting array of the pillars 34 is also a square or rectangular array having the same center-to-center pitch as the original array.

According to other example embodiments, the same methodology is applied to a square or rectangular array of openings, wherein one or more openings may be omitted from the array. An example thereof is shown in FIGS. 11A to 11C. FIG. 11A shows the original array of openings 30. FIG. 11B shows the resulting array, which now comprises pillars 34 as well as line-shaped features 35. FIG. 11C shows a superposition of the original openings 30 and the obtained array of pillars and lines. By selecting the location of omitted openings from the array, various arrays of pillars and line-shaped features can be produced. The disclosure thereby provides an alternative to conventional patterning methods for producing such patterns and which include the application of multiple lithographic masks, whereas the present disclosure provides (e.g., enables) obtaining such patterns using a single lithographic mask for producing a given array of openings 30.

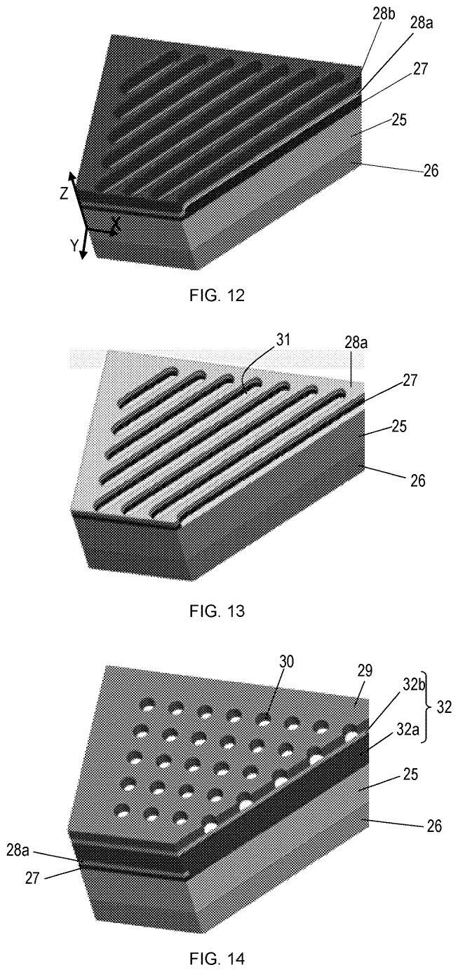

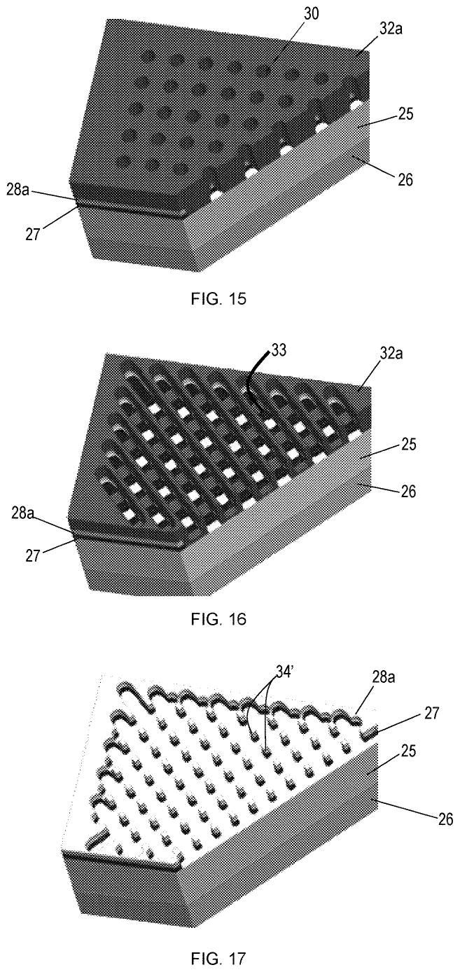

A further example embodiment is illustrated in FIGS. 12 to 18. The same mask layers and method steps are applied as described in relation to the first example embodiment; however, the scanning directions of the two directional etching steps are different. The steps described with reference to FIGS. 3 and 4 are therefore (e.g., equally) applicable to this further example embodiment. However, the first directional etching step is now performed in a scanning direction that is oriented at (e.g., about) 45° with respect to the X direction, as illustrated in FIG. 12. Scanning can be repeated several times in the same or in the opposite direction. The first trenches 31 are now formed by merging openings 30 in the direction of the diagonals of the square pattern. This provides (e.g., means) that the trenches 31 are closer together compared to the first example embodiment. After the first directional etch step, the hardmask layer 28b is stripped, as seen in FIG. 13, and the second mask layer 32 is produced in the same way as in the first example embodiment, as seen in FIG. 14. The square pattern of openings 30 is again formed in a resist layer 29 and transferred to the second mask layer, as illustrated in FIG. 15.

With reference to FIG. 16, the second directional etching step is then applied along a scanning direction perpendicular to the scanning direction of the first directional etching step, e.g., at (e.g., about) 135° with respect to the X-direction. Scanning can again be repeated several times in the same or in opposite directions. The second directional etching step is applied until the second trenches 33 are formed, oriented perpendicularly to the first trenches 31.

After removing (e.g., stripping) the hardmask layer 32a, a grid of pillars 34′ is obtained as shown in FIG. 17, which can be transferred to the target layer 25.

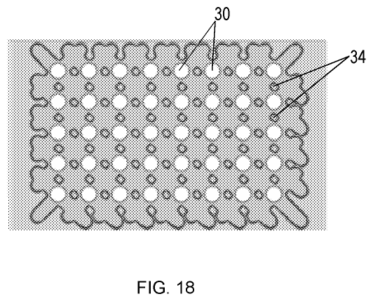

As illustrated in the superposed image in FIG. 18, the center-to-center pitch of the pillar grid is smaller (e.g., less) than the pitch of the original pattern of openings 30. In this example embodiment, an array having a pitch smaller than the pitch of the initial array of openings 30 can be produced. By starting from an array of openings 30 having a pitch close to the smallest pitch obtainable by standard lithography and etching, the present disclosure thereby provides (e.g., enables) producing an array of features at sub-resolution pitch.

The orientation of the scanning directions of the two directional etching steps is not limited to the above-described cases. For example, in the case of the rectangular array of openings 30 (with or without omission of selected openings) represented in the drawings, the scanning direction of the first step may be anywhere between the two orthogonal directions provided (e.g., defined) by the rows and columns of the array of openings 30. The scanning direction of the second directional etch step may be perpendicular to the first scanning direction, but other orientations are not excluded.

The array of openings 30 (with or without omissions) could be arranged according to another pattern instead of the rectangular pattern illustrated in the drawings, for example, a hexagonal pattern, which provides (e.g., enables) producing further variants of the resulting pillar and/or line patterns. Also, other applicable combinations of arrays of openings 30 and scanning directions of the first and second directional etching steps are included in the scope of the present disclosure.

The step of transferring the pattern of pillars 34, 34′, and/or lines 35 includes example embodiments wherein a tone reversal is performed before actually transferring the pattern, e.g., positive features (pillars and/or lines) are transformed to negative features (holes and/or trenches). This may be done by depositing a layer that fills the spaces between the pillars and/or lines, planarizing the layer, and selectively removing the pillars and/or lines with respect to the layer, to obtain holes and/or trenches. These holes and/or trenches are then transferred to the target layer 25.

The array of openings 30 applied in the method is a (e.g., regular) array of openings, e.g., an array of openings having the same in-plane dimensions (for example, circular holes as in the illustrated example embodiments) and arranged according to a repetitive pattern, such as the square array illustrated in the drawings. Other (e.g., regular) arrays can be used, for example, a hexagonal array wherein each opening is surrounded by six other openings at angular spacings of 60°. Such an array comprises rows and columns that are not perpendicular but are at an angle different from 90°. The etching directions of the directional etching steps applied in the method can be adapted to these directions, in order to obtain analogous results as described above for the example embodiments based on perpendicular rows and columns.

While some example embodiments have been illustrated and described in detail in the appended drawings and the foregoing description, such illustration and description are to be considered illustrative and not restrictive. Other variations to the disclosed example embodiments can be understood and effected in practicing the claims, from a study of the drawings, the disclosure, and the appended claims. The mere fact that certain measures or features are recited in mutually different dependent claims does not indicate that a combination of these measures or features cannot be used. Any reference signs in the claims should not be construed as limiting the scope.

What is claimed is:

1. A patterning method for use in a semiconductor production process, the method comprising:
forming a target layer on a support substrate;
forming an etch stop layer on the target layer and forming a first mask layer on the etch stop layer;
patterning the first mask layer to provide a pattern with a two-dimensional array of openings or a modified array obtained by omitting one or more openings from the two-dimensional array;
performing a first directional etching step selective to the etch stop layer, wherein the first directional etching step enlarges the openings in a first direction to form, in the first mask layer, an array of parallel line-shaped trenches oriented in the first direction;
forming a second mask layer over the first mask layer;
patterning the second mask layer according to the pattern of the array of openings;
performing a second directional etching step selective to the etch stop layer, wherein the second directional etching step enlarges the openings in the second mask layer in a second direction that crosses the first direction, so that the second mask layer is patterned into an array of parallel line-shaped trenches oriented in the second direction, and wherein the second directional etching step removes portions of the first mask layer exposed to etch species applied in the second directional etching step for patterning the first mask layer into a final pattern comprising at least one of an array of pillars or lines;
removing the second mask layer selectively relative to the at least one of the pillars or lines; and
transferring the pattern provided by the at least one of the pillars or lines to the target layer.

2. The method of claim 1, wherein the patterned first mask layer is thinned.

3. The method of claim 2, wherein the patterned first mask layer is thinned after the first directional etching step.

4. The method of claim 3, wherein the patterned first mask layer is thinned before forming the second mask layer.

5. The method of claim 1, wherein the pattern of the patterned first mask layer is transferred to the etch stop layer before forming the second mask layer.

6. The method of claim 5, wherein the pattern of the patterned second mask layer is transferred to the etch stop layer before transferring the pattern provided by the at least one of the pillars or lines to the target layer.

7. The method of claim 1, wherein the pattern of the patterned first mask layer is not transferred to the etch stop layer before forming the second mask layer.

8. The method of claim 7, wherein the pattern provided by the at least one of the pillars or lines is transferred to the etch stop layer.

9. The method of claim 8, wherein the pattern provided by the at least one of the pillars or lines is transferred to the etch stop layer before transferring the pattern provided by the at least one of the pillars or lines to the target layer.

10. The method of claim 1, wherein the array of openings is a rectangular array extending in two perpendicular directions with one or more openings omitted from the array.

11. The method of claim 10, wherein the first direction of the first directional etching step is aligned with at least a first perpendicular direction of the two perpendicular directions.

12. The method of claim 11, wherein the second direction of the second directional etching step is aligned with a second perpendicular direction of the two perpendicular direction.

13. The method of claim 1, wherein the array of openings is a rectangular array extending in two perpendicular directions.

14. The method of claim 13, wherein:
the first direction of the first directional etching step is positioned between the two perpendicular directions; and
the second direction of the second directional etching step is perpendicular to the first direction.

15. The method of claim 14, wherein the first direction is oriented at 45° relative to the two perpendicular directions.

16. The method of claim 14, wherein each opening has a circular cross-section shape.

17. The method of claim 1, wherein the first mask layer comprises a stack of sublayers including:
a first hardmask layer having a thickness t1;
a second hardmask layer having a thickness greater than t1; and
a third hardmask layer having a thickness approximately equal to t1.

18. The method of claim 17, wherein the third hardmask layer is consumed during transfer of the pattern of openings from a patterned resist layer to the first mask layer to the first mask layer, such that the first directional etching step is performed on a stack including the first and second hardmask layers.

19. The method of claim 17, wherein the second hardmask layer is removed selectively relative to the first hardmask layer before forming the second mask layer.

20. The method of claim 1, wherein the second mask layer comprises a stack of sublayers including:
a first hardmask layer having a thickness t1; and
a second hardmask layer having a thickness less than t1, and wherein the second hardmask layer is consumed during transfer of the pattern of openings from a patterned resist layer formed on the second mask layer to the second mask layer.
